(19) United States
(12) Patent Application Publication
(10) Pub. No.: US 2023/0251323 A1
(43) Pub. Date: Aug. 10, 2023

(54) DETERMINATION OF THE STATE OF HEALTH OF AN ELECTRIC ACCUMULATOR BY CONVERSION

(71) Applicant: Commissariat à l'Energie Atomique et aux Energies Alternatives, Paris (FR)

(72) Inventors: Fathia KAROUI HENCHIRI, Grenoble cedex 09 (FR); Jean-Marie KLEIN, Grenoble cedex 09 (FR); Maxime MONTARU, Grenoble cedex 09 (FR)

(73) Assignee: Commissariat à l'Energie Atomique et aux Energies Alternatives, Paris (FR)

(21) Appl. No.: 18/146,653

(22) Filed: Dec. 27, 2022

(30) Foreign Application Priority Data
Dec. 28, 2021 (FR) 21 14597

(51) Int. Cl. G01R 31/392; G01R 31/3842

(52) U.S. Cl. CPC G01R 31/392; G01R 31/3842

(57) ABSTRACT

A method for determination of a state of health indicator of an electrical accumulator includes converting a set of charge and discharge operations into an equivalent set of symmetrical reconstituted cycles and selecting the symmetrical reconstituted cycles. For each selected symmetrical reconstituted cycle the rate of energy supplied by the electrical accumulator during the discharge phase per unit of state of charge amplitude of the electrical accumulator and a total equivalent energy value for a complete charge of the electrical accumulator are determined. The method also includes determining a mean value from total equivalent energy values relating to a plurality of selected symmetrical reconstituted cycles and determining the state of health indicator of the electrical accumulator by dividing the mean value by the value of the nominal energy capacity of the electrical accumulator.

### TECHNICAL FIELD

The invention concerns the field of electrical accumulators, such as electrochemical accumulators, and is more particularly directed to techniques enabling an indicator representative of the ageing of an electrical accumulator to be determined.

### PRIOR ART

For the management of an electrical accumulator in general, and the management of its charge and discharge cycles, it may be advantageous, or even necessary, to have available an indicator representative of the ageing of the electrical accumulator. The indicator routinely employed is a parameter known as the state of health (SOH), which is generally calculated by dividing the capacity of the accumulator at the time concerned by the nominal capacity of the accumulator. As it ages the accumulator loses capacity and this loss is quantified by the state of health indicator, which indicates that the present capacity of the accumulator corresponds to a certain percentage of its nominal capacity, in particular of its capacity when new, or of its capacity as communicated by the manufacturer.

Electrical accumulators are generally associated with a battery management system (BMS) enabling monitoring of the charge and discharge cycles as well as multiple operations aiming to extend the service life of the accumulator. Present day battery management systems necessitate a great number of input parameters, with greater precision, in order to proceed to advance battery management operations.

Known techniques for determination of the state of health of a battery cell generally employ a measurement of the capacity of each cell of the electrical accumulator. To this end each cell is completely discharged and then completely charged, or completely charged and then completely discharged. The quantity of charge accumulated in the cell or extracted from the cell during the complete charging or complete discharging thereof can be measured by coulometric metering, which amounts to measuring the real capacity of the cell. Knowing the real capacity of the cell, the battery management system is then able to determine the state of health of the cell by dividing that real capacity by the nominal capacity of the cell. A disadvantage of these techniques for determination of the state of health is that they necessitate the use of a complete discharge of the cell followed by a complete charge or a complete charge followed by a complete discharge, which is relatively constraining. It is also difficult to apply in the case of more complex accumulators, including numerous cells connected in various subassemblies, and for which measurements at the cell level are not available.

The patent application DE102019111976 describes a method for determining the capacity of a battery using a partial charge or discharge. The method includes the determination of a first rest voltage at a first state of charge of the battery, the determination of a second rest voltage at a second state of charge of the battery, the determination of a quantity of discharge between the first state of charge and the second state of charge, the determination of a state of ageing of the battery and the determination of a reference quantity of charge on the basis of the first rest voltage, of the second rest voltage and of a reference rest voltage characteristic. In this case the characteristic no-load reference voltage curve depends on the state of ageing. The method also includes the determination of the capacity of the battery on the basis of a comparison between the level of discharge and the reference level of discharge. This method necessitates beforehand characterisation of the battery to obtain a no-load voltage characteristic at different states of ageing. This is costly, time-consuming and cannot be applied to complex assemblies of accumulators for which are available only specifications and measurements at the scale of that assembly. Moreover, the method in question estimates ageing without taking into account only the evolution of the electric current capacity.

The patent application US2008/0150491 describes a method enabling estimation of the real capacity of an accumulator cell from a partial charge of the cell. The state of charge variation of the cell necessary for obtaining a reliable estimate of its real capacity remains relatively high, however, which can pose a problem in some applications.

The patent application FR3018608 alleviates this problem using smaller state of charge evolutions. This method is however not applicable to accumulators for which the charging operation does not includes phases at constant voltage.

The following scientific publications describe the application of the rainflow counting method in the field of battery charging:
Huang et al. “A Novel Autoregressive Rainflow-Integrated Moving Average Modeling Method for the Accurate State of Health Prediction of Lithium-Ion Batteries.” Processes 2021, 9, 795. https://doi.org/10.3390/pr9050795;
Huang et al. “An Improved Rainflow Algorithm Combined with Linear Criterion for the Accurate Li-ion Battery Residual Life.” J. Electrochem. Sci., 16 (2021) Article ID: 21075. doi:10.20964/2021.07.29.

### STATEMENT OF INVENTION

The invention has for object improving the prior art methods for the determination of a state of health indicator of an electrical accumulator.

To this end, the invention is directed to a method for determination of a state of health indicator of an electrical accumulator, including the following steps:

determining the nominal energy capacity of the electrical accumulator;
acquiring measurements of parameters representative of the voltage at the terminals of the electrical accumulator, of the current delivered by the electrical accumulator, and of the state of charge of the electrical accumulator, this acquisition being effected over a period of measurement including a set of operations of charging and discharging the electrical accumulator;

a) converting the set of charge and discharge operations of the period of measurement into an equivalent set of symmetrical reconstituted cycles, each symmetrical reconstituted cycle including a charge operation and a discharge operation with the same state of charge amplitude;

b) selecting the symmetrical reconstituted cycles with a state of charge amplitude greater than the predetermine value;

c) for each selected symmetrical reconstituted cycle: determining the rate of energy supplied by the electrical accumulator during the discharge phase per unit of state of charge amplitude of the electrical accumulator: and determining a total equivalent energy value for a complete charge of the electrical accumulator;

d) determining a mean value from total equivalent energy values relating to a plurality of selected symmetrical reconstituted cycles and determining the state of health indicator of the electrical accumulator by dividing this mean value by the value of the nominal energy capacity of the electrical accumulator.

In accordance with another object, the invention is directed to a system configured to employ the method described for management of electrical energy storage systems, such as batteries.

In accordance with another object, the invention is directed to a computer program product comprising instructions that cause an electrical energy storage management system to execute the steps of the method described.

The method according to the invention determines the state of health of the accumulator directly from available data and in particular from data available in a classic battery management system, regardless of the scale at which that data is produced. In fact, an electrical accumulator may consist of one or more elementary cells, possible interconnected in accordance with different levels of complexity, so as to obtain an electrical generator with the desired voltage and capacity. In particular, an electrical accumulator may be:

a single elementary cell;

a module consisting of an interconnected set of these elementary cells;

a rack consisting of an assembly of modules;

a container consisting of an assembly of disconnectable racks;

a set of containers forming a storage centre.

Whatever the scale considered for an electrical accumulator of this kind, the method according to the invention determines the state of health of the accumulator at its scale, without necessitating measurements at the level of any subassemblies constituting the accumulator. The method according to the invention applies to any accumulator associated with electronic means enabling the necessary measurements of voltage, current and state of charge. Classic battery management systems are generally capable of supplying this data.

The method according to the invention requires no specific operation such as a complete charge or a complete discharge. No intrusion is necessary in the functioning of the battery, the determination of the state of health being obtained with data classically available, in a manner that is totally transparent over the charge and discharge cycles.

The invention enables estimation of the degraded state of health of the accumulators in terms of evolution of the available energy, which integrates at the same time the evolution of the capacity of the accumulator and the evolution of its resistance, without necessitating individual calculation of these magnitudes.

The invention in particular enables predictive maintenance based on a reliable and precise indication of the evolution of the capacity of the accumulator to store energy.

Similarly, finer management of the charge of the accumulator when on charge or on discharge is made possible by the invention. It is for example possible to determine with greater accuracy the precise moment at which charging the battery can be stopped (as soon as the battery has been topped up in terms of energy). It is also possible to determine the charge to be applied to the accumulator to dispose of a particular quantity of energy at the output. This kind of finer management of charging and discharging the accumulator makes a significant contribution to increasing the service life of the accumulators.

The method according to the invention may have the following additional features, separately or in combination:

in step a), the conversion into symmetrical reconstituted cycles is effected by combining in pairs increasing minima and decreasing maxima of the charge and discharge operations of the period of measurement:

in step a), the conversion is effected by application of the rainflow counting method;

in step c), the rate of energy supplied by the electrical accumulator during the discharge phase per unit of state of charge amplitude of the electrical accumulator is determined by dividing the energy discharged during the discharge cycle of the selected symmetrical reconstituted cycle by the charge amplitude of the selected symmetrical reconstituted cycle;

in step c), the total equivalent energy value of a selected symmetrical reconstituted cycle is determined by the following formula:

$${E}_{idx} = \frac{{DWh}_{idx}}{{SOC}_{idis} - {SOC}_{fdis}} \times 100$$

in which:

E_{idx} is the total equivalent energy of the selected reconstituted cycle;

DWh_{idx} is the integral of the power discharged during the discharge operation of the selected reconstituted cycle;

SOC_{idis} is the initial state of charge during the discharge operation of the selected reconstituted cycle;

SOC_{fdis} is the final state of charge during the discharge operation of the selected reconstituted cycle;

the value of the total equivalent energy for each symmetrical reconstituted cycle is divided by the number of disconnectable subassemblies that constitute the electrical accumulator;

in step b), the selected symmetrical reconstituted cycles are those in which the amplitude of variation of the state of charge or of the voltage is greater than a predetermined value;

in step b), said predetermined value is equal to 10%;

in step d), said mean value is determined by calculating an olympic mean of the total equivalent energy values;

in step d), said mean value is a sliding mean over a plurality of selected symmetrical reconstituted cycles in which the corresponding total equivalent energy value is situated in a range between a predetermined minimum threshold and a predetermined maximum threshold;

in step d), said total equivalent energy values relating to each selected symmetrical reconstituted cycle comprise a number of values greater than a predetermined minimum value;

said predetermined minimum value is 10:

the nominal energy capacity of the electrical accumulator is present in memory in a battery management system connected to the electrical accumulator;

the nominal energy capacity of the electrical accumulator is determined by measurement during a first complete charge and discharge cycle on commissioning the electrical accumulator;

said measurements of parameters representative of the voltage at the terminals of the electrical accumulator, of the current delivered by the electrical accumulator and of the state of charge of the electrical accumulator are produced by a battery management system connected to the electrical accumulator.

### DESCRIPTION OF THE FIGURES

Other features and advantages of the invention will emerge from the following non-limiting description with reference to the appended drawings, in which:

FIG. 1 illustrates a simplified example of sets of charge and discharge cycles of an electrical accumulator;

FIG. 2 illustrates an equivalent set of cycles reconstituted from the set of cycles in FIG. 1;

FIG. 3 illustrates a first real example of sets of charge and discharge cycles of an electrical accumulator;

FIG. 4 illustrates a second real example of sets of charge and discharge cycles of an electrical accumulator;

FIG. 5 is a flowchart illustrating part of the method according to the invention;

FIG. 6 is a first illustration of values obtained by the method according to the invention;

FIG. 7 is a second illustration of values obtained by the method according to the invention.

### DETAILED DESCRIPTION

The method according to the invention alms to determine the state of health of an electrical accumulator. The accumulator may be any accumulator provided with a battery management system able to furnish the voltage, the current and the state of charge of the accumulator. The state of charge (SOC) is an indicator giving the ratio between the present charge of the accumulator and its present total capacity. This data is well-known in the field of battery management and is preferably delivered directly by the battery management system. The method according to the invention can itself be implemented by the battery management system or by a global energy management system (EMS) at the scale of the electrical power plant.

In addition to this data, execution of the method necessitates a knowledge of the nominal energy capacity of the accumulator. This value corresponds to the total energy that the accumulator can contain at full charge and before any ageing. The nominal energy capacity may be data from the manufacturer of the accumulator and may be stored in the battery management system. The nominal energy capacity can also be calculated by the battery management system or measured during a first use, during a complete discharge phase, by continuously measuring the voltage and the current, to obtain an energy value (generally expressed in Wh).

The electrical accumulator may be any accumulator, whatever its scale, associated with a battery management system, in particular an elementary cell, a battery, a module, a rack, a container, a storage system.

In the present example the electrical accumulator is a container formed of a plurality of disconnectable racks. This particular embodiment of the method also necessitates an indicator relating to the number of racks present at any time in the container forming the battery energy storage system (BESS). This information can also be supplied by the battery management system.

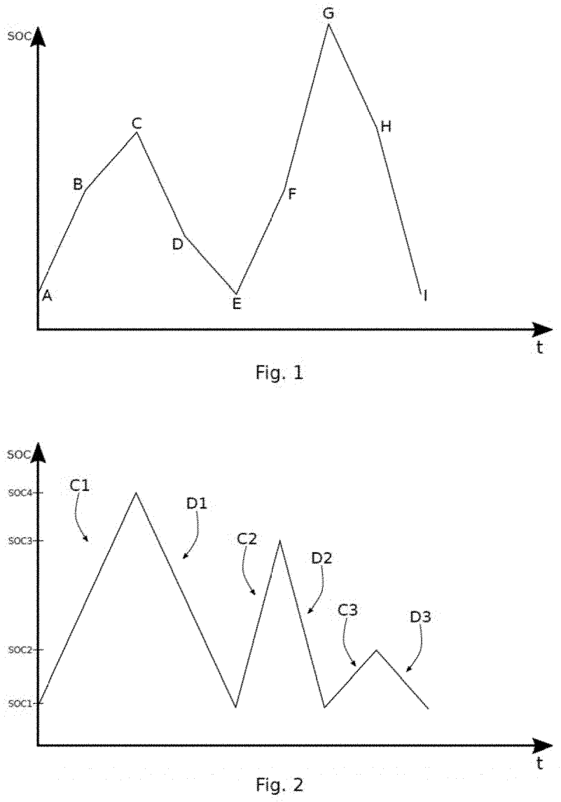

The method for determination of the state of health of the accumulator is executed in an acquisition time window known as the “period of measurement”. FIG. 1 illustrates a simple example of the evolution of the state of charge SOC of the electrical accumulator as a function of time t over the period of measurement PM. The period of measurement PM includes a set of operations of charging and discharging the accumulator, all the data referred to as to voltage, current and state of charge of the accumulator having been obtained during this period of measurement PM. The period of measurement PM may be static or sliding, that is to say updated as measurement proceeds.

A first measurement step consists in converting all the charge and discharge operations that are effected on the accumulator during the period of measurement PM into an equivalent set of cycles. A cycle includes a charging operation and a discharging operation. The cycles resulting from this conversion are referred to as “reconstituted” because they result from a reorganisation, possibly with approximation, of the real cycles from FIG. 1.

Although taken here by way of example, the reconstitution of charge/discharge cycles with the main aim of identifying discharge cycles serving as a basis for analysis, any other method enabling identification of the discharge operations during a period of measurement is applicable to the invention.

FIG. 2 illustrates the principles on which such conversion is based. FIG. 1 relating to a theoretical example of the life of the accumulator, highly simplified for didactic purposes, FIG. 2 illustrates an example of the equivalent set of reconstituted cycles.

In this illustrative example the accumulator is subjected successively to (see FIG. 1):

a charge operation leading to an increase in the state of charge over a first slope (segment AB) and then over a second slope (segment BC);

a discharge operation leading to a reduction in the state of charge over a first slope (segment CD) and then over a second slope (segment DE);

a second charge operation leading to an increase in the state of charge over a first slope (segment EF) and then over a second slope (segment FG):

a second discharge operation leading to a reduction in the state of charge over a first slope (segment GH) and then over a second slope (segment HI).

In this trivial example the set of real charge and discharge cycles from FIG. 1 is converted into the equivalent set of reconstituted cycles in FIG. 2, in the following manner:

segments AB and EF are placed end to end to form the charge operation C1 of a first reconstituted cycle;

segments CD and GH are placed end to end to form the discharge operation D1 of the first reconstituted cycle;

segment FG constitutes the charge operation C2 of a second reconstituted cycle and the segment HI constitutes the discharge operation D2 of this second reconstituted cycle;

the segment BC constitutes the charge operation C3 of a third reconstituted cycle and the segment DE constitutes the discharge operation D3 of this third reconstituted cycle.

The first reconstituted cycle increases the state of charge of the accumulator from a minimum value SOC1 to a maximum value SOC4, after which a discharge operation reduces the state of charge from this maximum value SOC4 to the initial value SOC1. The second reconstituted cycle increases the state of charge from the value SOC1 to a maximum value SOC3, then returns the state of charge to the initial value SOC1. The third reconstituted cycle increases the state of charge from the value SOC1 to a maximum value SOC2, then reduces the state of charge to the initial value SOC1.

In the FIG. 2 illustration the reconstituted cycles are symmetrical, although the symmetry of these cycles is not obligatory for use of the method, the only imperative data item for which is the knowledge of a plurality of discharge operations.

However, in order to estimate the state of health it is preferable to use the discharge phases of symmetrical cycles or of symmetrical reconstituted cycles instead of the discharge phases of any cycle whatever. This use improves the accuracy of estimation because of the cancellation of the effect of the history of use of the battery on the estimated value. The inventors have therefore shown that the values obtained of the state of health over a discharge preceded by a charge of the same amplitude of state of charge variation (i.e. symmetrical cycles) are more accurate than those obtained from a discharge phase preceded by a charge with a different state of charge variation amplitude different from, for example greater than, the discharge. These advantages are also obtained for the symmetrical reconstituted cycles.

For some applications, for which the charge/discharge cycles are simple and regular, a relatively simple algorithm will take charge of this conversion, as illustrated in FIGS. 1 and 2. However, many applications relate to complex and irregular charge and discharge cycles. In this case more sophisticated algorithms will be used for the conversion operation described. In the present example, a preferred implementation concerns the use of the rainflow counting method developed originally in the field of materials for estimates of cyclic fatigue and nowadays used in numerous applications where a cyclic behaviour can be observed, in particular in wind turbines, rotating machines and battery charging.

The rainflow counting method consists in associating in pairs increasing minima and decreasing maxima of the initial curve and can be implemented by numerous known algorithms.

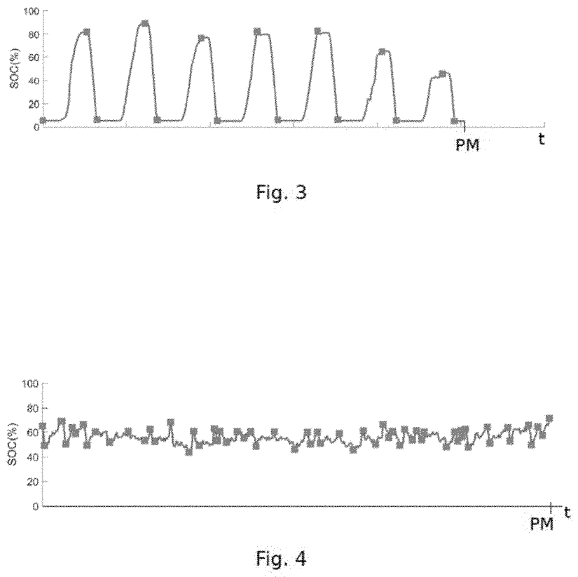

FIGS. 3 and 4 illustrate two real examples of a period of measurement PM including a set of charge and discharge operations for an electrical accumulator. FIG. 3 illustrates a first charge/discharge profile of relatively high value and relatively regular in the set, despite a few local irregularities. FIG. 4 illustrates another charge/discharge profile having a lower charge amplitude and the charge and discharge operations of which are very irregular.

For these two illustrative profiles, the use of an algorithm implementing the rainflow cycle metering method will in each case enable effective conversion into an equivalent set of reconstituted cycles. In FIGS. 3 and 4 the solid squares represent points of inflexion that are taken into account for the creation of the segments that will form the reconstituted cycles. This operation is carried out by associating in pairs increasing maxima and decreasing maxima in accordance with the rainflow counting method.

To this end it is preferable to be able to set a state of charge amplitude beyond which a discharge operation will be taken into account in the conversion. For example, a 1% threshold will result in any discharge operation having a discharge depth less than 1% not being taken into account in the conversion operation.

At the end of this conversion step the battery management system therefore has an equivalent set of reconstituted cycles relating to the period of measurement.

The method then includes a filtering step in which only some reconstituted cycles are selected. The battery management system uses a predetermined state of charge amplitude value beyond which a reconstituted cycle will be selected. In the present example this predetermined value is greater than 5% and preferably greater than 10%. In other words, only reconstituted cycles for which the charge and discharge amplitude will be greater than 10% will be selected for the remaining operations, the other cycles being ignored. Note that the method according to the invention enables the taking into account of discharge operations even of small amplitude (close to 10%), which increases the spectrum of measurements on which is based the estimate of the state of health of the accumulator, and which therefore increases the accuracy of that estimate.

Setting the threshold (here 1%) and the predetermined value (here 10%) makes the method applicable to numerous charge and discharge profiles and does not necessitate access to a particular phase such as a constant voltage phase, a rest phase, etc. The method can therefore be applied to all profiles, even the most irregular and the most chopped up, without intrusion on the functioning of the charge and discharge cycles.

The method then includes a calculation step in which the total equivalent energy for a complete charge of the accumulator is determined for each reconstituted cycle selected in the preceding step. Here the total equivalent energy denotes the total energy that the battery is capable of delivering after a complete charge, in the light of its behaviour during the discharge operation of the reconstituted cycle concerned.

For this calculation the battery management system proceeds to Integrate the power discharged from the accumulator over the entire discharge phase of the selected reconstituted cycle concerned. This power is equal to the product of the current (real current, measured over the period of measurement PM) by the voltage of the accumulator (real voltage, also measured during the period of measurement PM). This integration is effected for the discharge operation of each of the reconstituted cycles that have been selected. If the parameters measured over the period of measurement PM take the form of a set of discrete values, this integration takes the form of a sum.

The result of the integration is a quantity of energy (expressed for example in Wh) relating to a reconstituted cycle. For a selected reconstituted cycle denoted idx, this quantity of energy corresponds to a state of charge difference denoted:

SOC_{ids}−SOC_{fdis}

where SOC_{idis} is the initial state of charge of the reconstituted cycle and SOC_{fdis} is the final state of charge of the cycle idx.

By dividing the integral of the power (thus of the energy) discharged during the discharge operation of the selected reconstituted cycle (parameter DWh_{idx} in the formula below) by the charge amplitude concerned (SOC_{idis}−SOC_{fdis}), there is obtained the energy supplied by the accumulator during the discharge phase per unit of state of charge amplitude. Multiplying this value by 100 yields the total equivalent energy for a complete charge of the accumulator.

Thus for each of the selected reconstituted cycles idx the calculation formula is here as follows:

$${E}_{idx} = \frac{{DWh}_{idx}}{{SOC}_{idis} - {SOC}_{fdis}} \times 100$$

In which:

E_{idx} is the total equivalent energy of the selected reconstituted cycle idx;

DWh_{idx} is the integral of the power discharged during the discharge operation of the selected reconstituted cycle idx;

SOC_{idis} is the initial state of charge during the discharge operation of the selected reconstituted cycle idx;

SOC_{fdis} is the final state of charge during the discharge operation of the selected reconstituted cycle idx.

At this stage of the method there are available as many values E_{idx} as selected reconstituted cycles over the period of measurement PM.

The method being applied, in the present example, to a container formed of a set of racks each of which is disconnectable, the method may here include an optional step enabling avoidance of sudden variations of the state of health indicator that will in the final analysis be determined, in the event of modification of the number of racks connected in the container and not caused by ageing. The aim is not to impute mere disconnection of a rack in the container to an ageing phenomenon. In this case the calculation of the state of health is preferably based on the energy at the scale of the racks, rather than at the scale of the container. The value of the total equivalent energy for each reconstituted cycle is therefore divided by a number of disconnectable subassemblies (here the racks) that constitute the electrical accumulator (here the container).

Accordingly, for each reconstituted cycle idx, the energy E_{idx} previously calculated is then divided by the number of racks available at the end of the discharge operation of the cycle idx concerned, according to the following equation:

$${E}_{i} = \frac{{E}_{idx}}{NbR}$$

with:

Eᵢ: total equivalent energy of the selected reconstituted cycle for a rack of the container;

NbR: number of (connected) racks available.

The method then proceeds to a step aimed at determining a mean value from the total equivalent energy values relating to a plurality of selected reconstituted cycles.

In accordance with a first example this step is a simple mean calculated from all the values Eᵢ (or the values E_{idx}, if the calculation step yielding the energy per rack Is not used) to obtain a mean total equivalent energy value relating to all the selected reconstituted cycles in the period of measurement.

In accordance with a second, more robust example, the values Eᵢ (or values E_{idx} if the calculation step yielding the energy per rack is not used) are averaged by calculating a sliding olympic mean over a certain number of values (for example 30 values). The olympic mean of a data series is the mean of the elements of that series from which the smallest and the largest have been removed, or from which has been removed a percentage of observation at the lower and upper ends of the distribution, so as to exclude the extreme observations.

For this sliding mean example, the period of measurement PM is also sliding, being progressively updated.

This averaging step can optionally be triggered only for the energy values idx that are in a predetermined range. In the present example the upper bound Emax of the range is the nominal capacity in energy Enom of the accumulator and the lower bound Emin is that same energy Enom multiplied by the state of health SOH that is the minimum for the validity of the model (which is dependent on the case study).

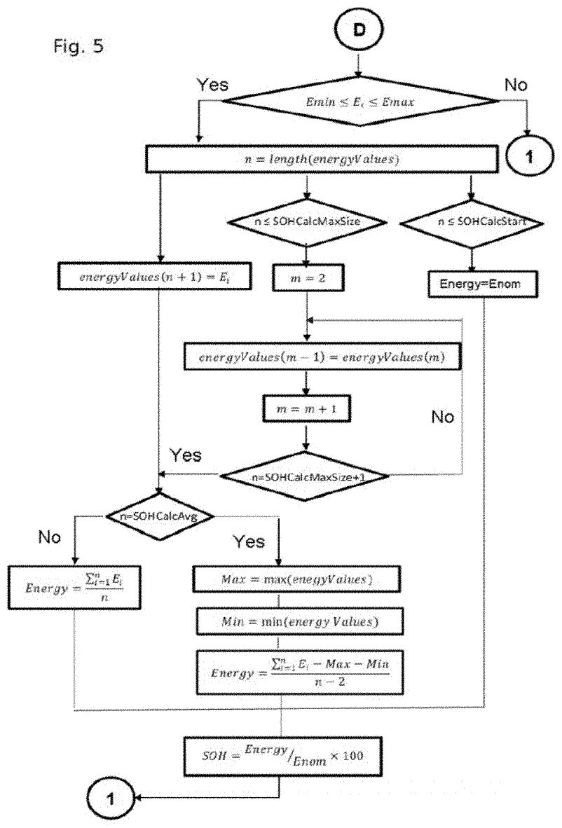

FIG. 5 is an illustrative example of the step of determination of the mean, with a sliding olympic mean and a predetermined range. In FIG. 5 the D illustrates the triggering of the averaging operation and the operation 1 illustrates the end of the method. The parameters illustrated in FIG. 5 are as follows:

Energy: the mean value of the total equivalent energy values relating to a plurality of selected reconstituted cycles;

Emin, Emax: bounds of the predetermined range (see above);

Eᵢ: energy capacity per rack of the accumulator;

n=length(energyValues): n corresponds to the number of energy values to be averaged;

SOHCalcMaxSize: number of energy values for calculation of the sliding mean (here 30 values);

SOHCalcStart: number of energy values for calculation of the SOH; if the number of values is less that SOHCalcStart, the SOH determined is 100%. (here, SOHCalcStart=10);

SOHCalcAvg: number of energy values before calculation of the olympic mean. As long as the table of energies contains a number of points less than or equal to SOHCalcAvg, a classic (not olympic) mean is calculated (here, SOHCalcAvg=10 to 15).

A final step (illustrated by the final step in FIG. 5) consists in obtaining the value of the required state of health SOH indicator. This value is obtained by dividing the Energy mean obtained previously by the value of the nominal energy capacity Enom of the accumulator. This operation can be multiplied by 100 (as in FIG. 5) to obtain the state of health SOH expressed as a percentage.

The state of health SOH is expressed in terms of a loss of capacity to store energy relative to the nominal capacity, in a manner that is updated for each new period of measurement (or of slippage of the period PM) without intrusion into the functioning of the charge and discharge cycles.

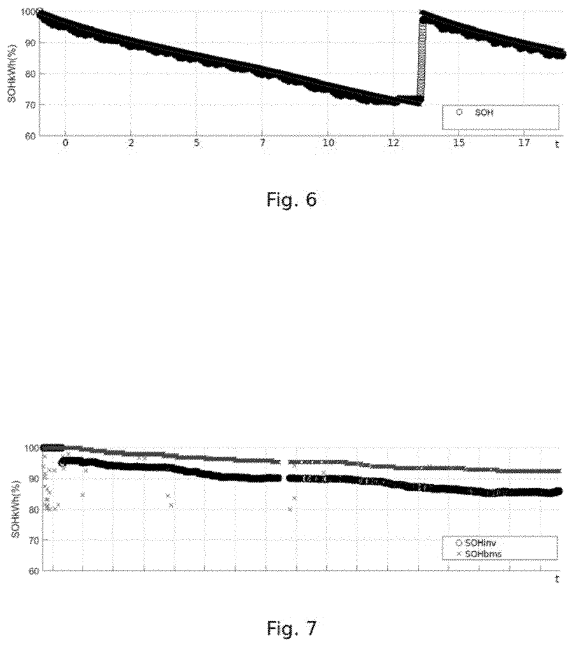

FIG. 6 illustrates the application of the method according to the invention, using the variants from FIG. 5, to determine the evolution of the state of health SOH of an accumulator (here a container) over a very large number of charge/discharge cycles corresponding here to 17 years of use. On the graph the state of health SOH therefore begins at 100% in year zero (new batteries). As the charge and discharge cycles proceed the state of health of the accumulator decreases to a value of 70% in year 12 (the accumulator then having only 70% of its initial energy storage capacity). After year 12 a maintenance operation leads to changing the batteries constituting the accumulator. This is immediately apparent on the graph, in accordance with the method described, and the state of health indicator is reset to 100%. The method according to the invention therefore offers great robustness on changes of battery or other events modifying the SOH value, unlike the prior art that generally necessitates a setting of parameters of the battery management system when replacing the batteries and lengthy recalibration.

FIG. 7 illustrates a comparison between the curve of evolution of the state of health SOHinv calculated by the method according to the invention and the curve of evolution of the state of health SOHbms calculated in the conventional manner by the battery management system over a period of measurement corresponding approximately to four years of use.

The results of the method according to the invention yield a more correct state of health, which in this example is below the state of health estimated in the classical manner that fluctuates much less, without disparate points.

1. A method for determination of a state of health indicator of an electrical accumulator, comprising:
determining a nominal energy capacity of the electrical accumulator; and
acquiring measurements of parameters representative of a voltage at terminals of the electrical accumulator, of a current delivered by the electrical accumulator, and of state of charge of the electrical accumulator, the acquiring being carried out over a period of measurement including a set of operations of charging and discharging the electrical accumulator;
converting the set of charge and discharge operations of the period of measurement into an equivalent set of symmetrical reconstituted cycles, each symmetrical reconstituted cycle including a charge operation and a discharge operation with the same state of charge amplitude;
selecting the symmetrical reconstituted cycles with a state of charge amplitude greater than a predetermined value;
for each selected symmetrical reconstituted cycle, determining a rate of energy supplied by the electrical accumulator during a discharge phase, per unit of state of charge amplitude of the electrical accumulator, and determining a total equivalent energy value for a complete charge of the electrical accumulator; and
determining a mean value from total equivalent energy values relating to a plurality of selected symmetrical reconstituted cycles and determining the state of health indicator of the electrical accumulator by dividing the mean value by a value of the nominal energy capacity of the electrical accumulator.

2. The method according to claim 1, wherein, in the converting, the conversion into symmetrical reconstituted cycles is carried out by combining in pairs of increasing minima and decreasing maxima of the charge and discharge operations of the period of measurement.

3. The method according to claim 2, wherein, in the converting, the conversion is carried out by application of the rainflow counting method.

4. The method according to claim 1, wherein the rate of energy supplied by the electrical accumulator during the discharge phase, per unit of state of charge amplitude of the electrical accumulator, is determined by dividing energy discharged during the discharge operation of the selected symmetrical reconstituted cycle by a charge amplitude of the selected symmetrical reconstituted cycle.

5. The method according to claim 4, wherein the total equivalent energy value of a selected symmetrical reconstituted cycle is determined by the following formula:
$${E}_{idx} = \frac{{DWh}_{idx}}{{SOC}_{idis} - {SOC}_{fdis}} \times 100$$
in which:
E_{idx} is the total equivalent energy of the selected reconstituted cycle;
DWh_{idx} is an integral of the power discharged during the discharge operation of the selected reconstituted cycle;
SOC_{idis} is an initial state of charge during the discharge operation of the selected reconstituted cycle; and
SOC_{fdis} is a final state of charge during the discharge operation of the selected reconstituted cycle.

6. The method according to claim 1, wherein the value of the total equivalent energy for each symmetrical reconstituted cycle is divided by a number of disconnectable subassemblies that constitute the electrical accumulator.

7. The method according to claim 1, wherein the selected symmetrical reconstituted cycles are those in which an amplitude of variation of the state of charge or of the voltage is greater than a predetermined value.

8. T method according to claim 1, wherein the predetermined value is equal to 10%.

9. The method according to claim 1, the mean value is determined by calculating an olympic mean of the total equivalent energy values.

10. The method according to claim 1, wherein the mean value is a sliding mean over a plurality of selected symmetrical reconstituted cycles in which a corresponding total equivalent energy value is situated in a range between a predetermined minimum threshold and a predetermined maximum threshold.

11. The method according to claim 1, wherein the total equivalent energy values relating to each selected symmetrical reconstituted cycle comprise a number of values greater than a predetermined minimum value.

12. The method according to claim 11, in which the predetermined minimum value is 10.

13. The method according to claim 1, wherein the nominal energy capacity of the electrical accumulator is present in memory in a battery management system connected to the electrical accumulator.

14. The method according to claim 1, wherein the nominal energy capacity of the electrical accumulator is determined by measurement during a first complete charge and discharge cycle on commissioning the electrical accumulator.

15. The method according to claim 1, wherein the measurements of parameters representative of the voltage at the terminals of the electrical accumulator, of the current delivered by the electrical accumulator, and of the state of charge of the electrical accumulator, are produced by a battery management system connected to the electrical accumulator.

16. An electrical energy storage management system configured to employ the method according to claim 1.

17. A computer program product comprising instructions that, when executed, cause an electrical energy storage management to execute the method according to claim 1.
